(19) United States
(12) Patent Application Publication
(10) Pub. No.: US 2007/0234189 A1
(43) Pub. Date: Oct. 4, 2007

(54) System and method for reducing false alarm in the presence of random signals

(76) Inventors: Sharon Levy, Hadera (IL); Rotem Avivi, Petah-Tikwa (IL)

Correspondence Address: SCHWEGMAN, LUNDBERG, WOESSNER & KLUTH, P.A., P.O. BOX 2938, MINNEAPOLIS, MN, 55402, US

(21) Appl. No.: 11/396,329

(22) Filed: Mar. 31, 2006

(51) Int. Cl. H03M 13/03

(52) U.S. Cl. 714/794

(57) ABSTRACT

System and methods for reducing false alarm in the presence of random signals are disclosed. Various embodiments are operable to receive via a data interface a data block having at least one frame, normalize soft bits of the data block and re-encode decoder output bits of the data block, calculate a normalized correlation metric from the normalized soft bits and re-encoded bits of the data block, compare the normalized correlation metric to a threshold, and reject the data block when the normalized correlation metric is below the threshold.

### BACKGROUND

1. Technical Field

This disclosure relates to data communications. More particularly, the present disclosure relates to reducing false alarm in the presence of random signals.

2. Related Art

Global System for Mobile Communications (GSM) is one of the leading digital cellular systems. GSM uses narrowband TDMA (time division multiple access), which allows eight simultaneous calls on the same radio frequency. In the GSM standard, class 1a bits are being protected by both a cyclic redundancy code (CRC) and convolution code. The CRC typically has K bits (e.g., NumOfCrcBits=3). In the receiver, the CRC bits are calculated and compared to the transmitted CRC bits (which were calculated in the transmitter). If the comparison fails, the block is declared to be an erroneous block. When a random signal is received, the probability that the block will not be declared as erroneous is 2^{-NumOfCrcBits}, where NumOfCrcBits is the number of CRC bits used by the cyclic code.

CRC error misdetection has an effect on the voice quality in cellular communication; therefore, tight requirements on the error misdetection rate are enforced. For GSM, the error misdetection rate is defined in a 3rd Generation Partnership Project (3GPP) Technical Specification (TS 05.05) as less than 1 misdetection per minute (i.e. ˜0.03%). Comparison of this error misdetection rate requirement and the CRC misdetection rate (12.5% for 3 bits CRC) forces many system designers to include additional criteria for block error detection to reduce the error misdetection rate. However, additional error detection systems (e.g. to increase the number of CRC bits) and processes add to the cost of the overall system and reduce the potential bandwidth. An improved error detection implementation is needed.

Thus, systems and methods for reducing false alarm in the presence of random signals are needed.

### BRIEF DESCRIPTION OF THE DRAWINGS

Embodiments illustrated by way of example and not limitation in the figures of the accompanying drawings, in which:

FIG. 1 is a system diagram illustrating an embodiment for reducing false alarm in the presence of random noise in accordance with the systems and methods described herein.

FIGS. 2a and 2b are flow diagrams illustrating an embodiment for reducing false alarm in the presence of random noise in accordance with the systems and methods described herein.

FIGS. 3a and 3b are flow diagrams illustrating an embodiment of the normalization and re-encoding process for reducing false alarm in the presence of random noise.

FIGS. 4a and 4b illustrate the accumulated probability of the normalized correlation metric in an embodiment and the generation of a threshold to determine random noise from a valid code word.

FIGS. 5a and 5b are block diagrams of a computing system on which an embodiment may operate and in which embodiments may reside.

### DETAILED DESCRIPTION

Systems and methods for reducing false alarm in the presence of random signals are disclosed. In the following description, numerous specific details are set forth. However, it is understood that embodiments may be practiced without these specific details. In other instances, well-known processes, structures and techniques have not been shown in detail in order not to obscure the clarity of this description.

Various embodiments described and claimed herein implement a system and method for reducing false alarm in the presence of random noise. The various embodiments implement an erroneous block detector which, in one embodiment, uses rate distortion computation to discriminate between a valid frame and random bits (e.g. random due to different encryption of neighbor users). These example embodiments will be described in more detail below.

In a conventional GSM-based network, a data block of a frame is typically interleaved on eight frames. In the conventional approach, the Signal to Noise ratio (SINR) is estimated based on the known transmitted training sequence for each frame. When a random signal is received, usually all the bits of the frame appear random (due to encryption). Although the standard test does not include them, there could be situations where the interfering base is synchronized to the wanted base and has a similar training sequence. Those scenarios would happen in high channel reuse (e.g. ⅓ or 1/1). In those cases, the SINR as the sole criterion is not good enough (because the training sequence will be valid) and the data bits at the equalizer output will have relatively strong metrics, but with random sign. By using the averaged SINR as the sole criterion for block validation, the conventional approach may degrade false block rejection performance in some cases. In addition, for some cases, especially high-speed channels, the noise estimation is misleading because it was calculated only during the training sequence interval. Therefore, it is important to take convolution codes structures into consideration. The various novel embodiments described and claimed herein make a GSM communication device more robust and improve false block rejection performance.

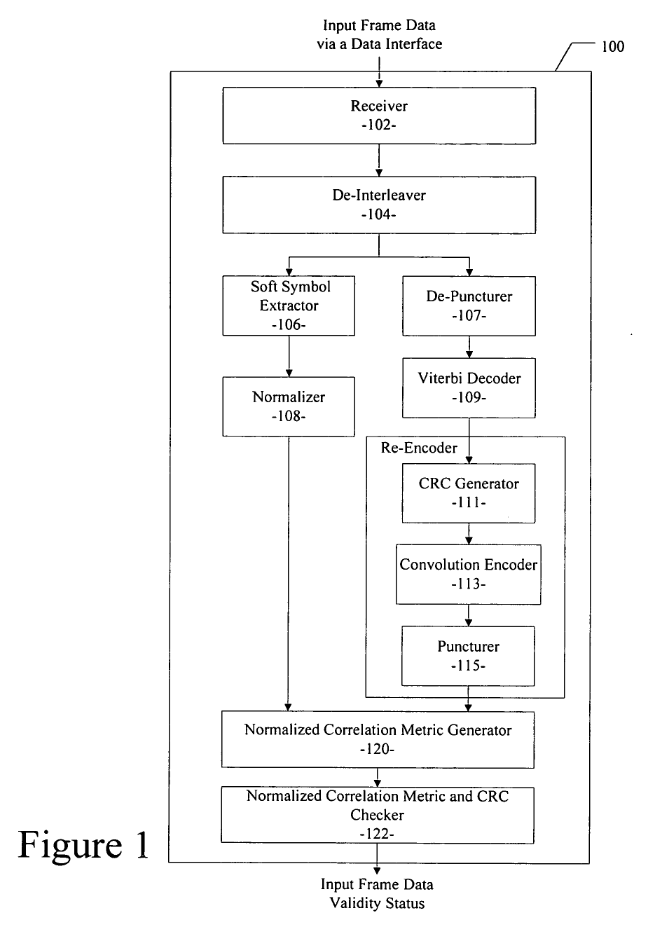

FIG. 1 is a system diagram illustrating an embodiment of an erroneous block detector 100 for reducing false alarm in the presence of random noise in accordance with the systems and methods described herein. The system 100 of FIG. 1 can be implemented, for example, in a GSM modem. In this example, eight input frames are received as data blocks provided as input to receiver 102. In various embodiments, data blocks can be received by receiver 102 from a conventional source of data provided as input through a data interface to, for example, a GSM modem. In a GSM embodiment, the data interface is a GSM data interface. These frames, as received, are equalized and interleaved. A de-interleaving operation is performed on the frames by de-interleaver module 104. Then, soft symbols are extracted by the soft symbol extractor 106. In addition, a de-puncturing operation is performed on the input data by a de-puncturer 107. A Viterbi decoder 109 then performs a decoding operation on the input frame data bits. After the Viterbi decoder 109 operation, the un-coded bits from the input data block are re-encoded. First, a CRC generator 111 generates a CRC value from the input data block. A convolution encoder 113 encodes the data with the ½ rate convolution code. A puncturer 115 then performs a puncturing operation on the coded bits to produce, in one embodiment, 378 re-coded hard bits. These re-encoded bits can be provided as input to the normalized correlation metric generator 120, which generates the normalized correlation metric as will be described in more detail below. Finally, a normalized correlation metric and CRC checker 122 checks the generated normalized correlation metric and the CRC value of the input data block to produce an input frame data validity status value. This status value can be used to determine if the input data block has been determined to be a good block or an erroneous block, as will be described in more detail below.

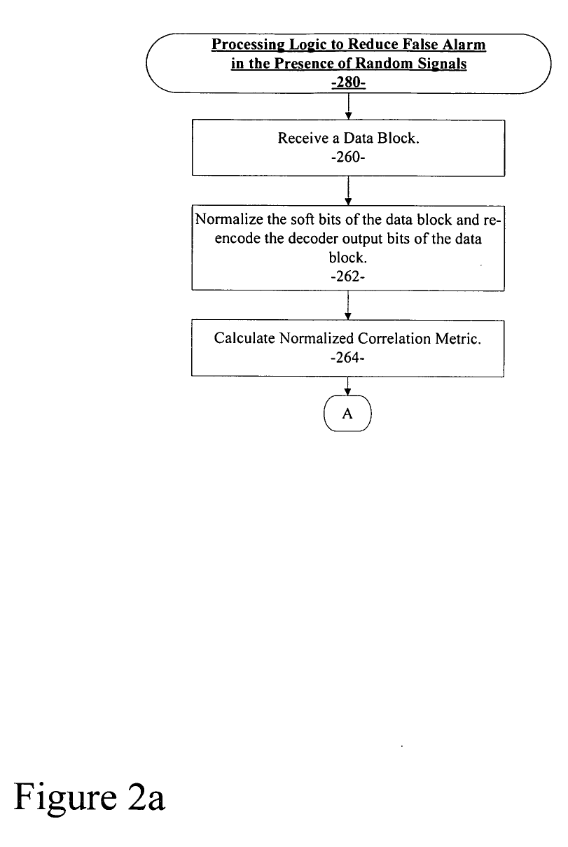

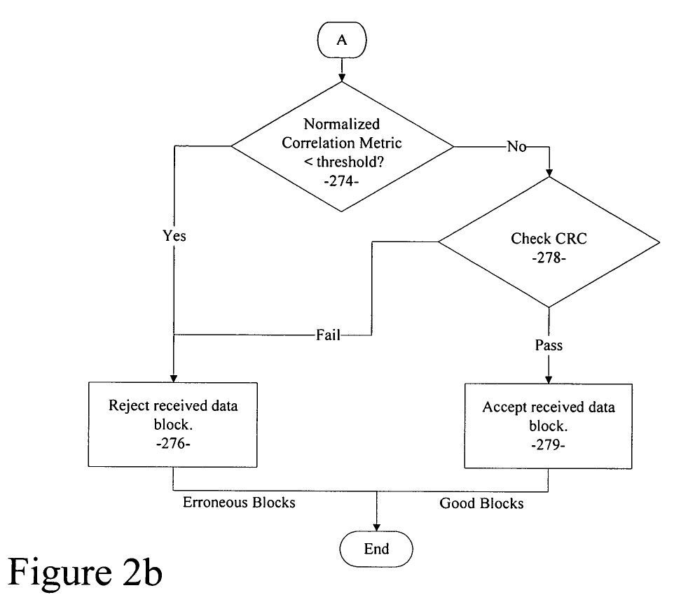

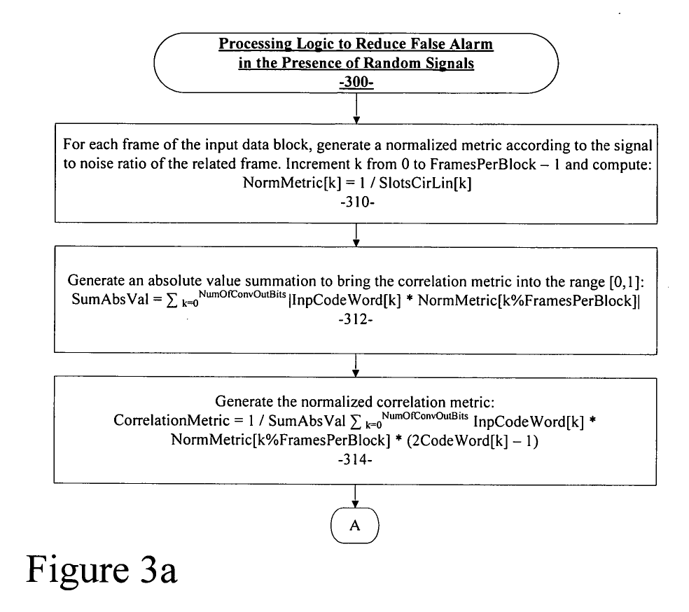

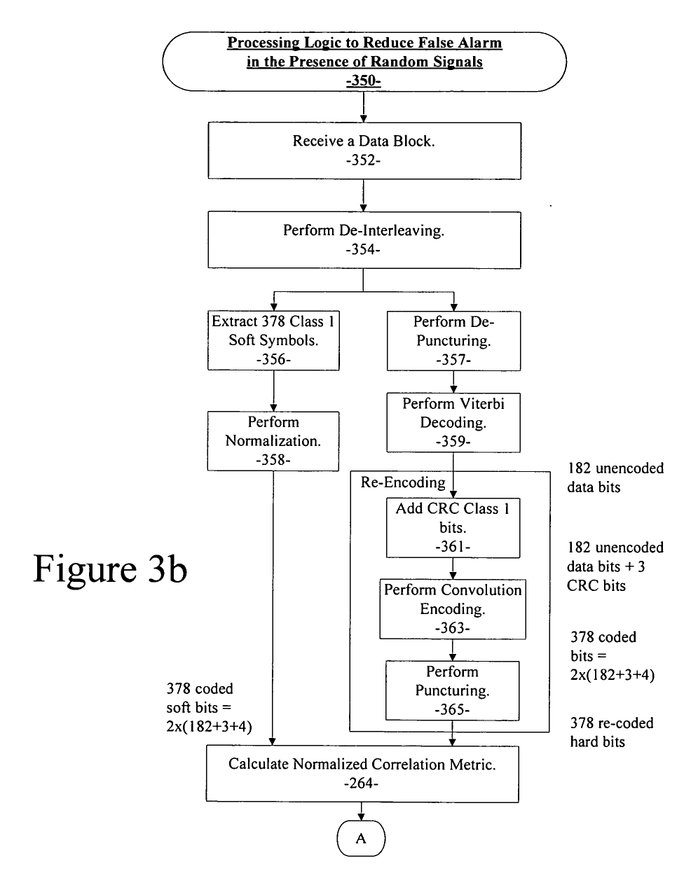

In FIGS. 2a and 2b, a flow diagram illustrates an example embodiment. Referring to FIG. 2a, a data block is received in processing block 260. In various embodiments, data blocks can be received by a receiver 102 from a conventional source of data provided as input to, for example, a GSM modem. In processing block 262, soft bits of the input data block are normalized and decoder output bits of the input data block are re-encoded. This soft bits normalization and decoder output re-encoding process is illustrated and described in more detail in connection with FIGS. 3a and 3b. Next, a novel normalized correlation metric is calculated (processing block 264). This correlation metric provides information about the distance between a valid code word and random noise. To derive this metric, the soft symbols (which are extracted after equalization, as performed inside block 352, as illustrated in FIG. 3b) are correlated with the hard re-encoded symbols. Processing then continues at the bubble A illustrated in FIG. 2b, where the generated normalized correlation metric and the CRC value of the input data block is checked.

Turning to FIG. 2b, the correlation metric is compared with a threshold to decide whether to declare this block as erroneous or not (decision block 274). Rate distortion theory is used to derive the threshold based in part on a rate distortion computation. In an example embodiment, if the computed normalized correlation metric is below the threshold, the received data block is rejected as an erroneous block (processing block 276). If the computed normalized correlation metric is at or above the threshold, the CRC of the data block is checked against a computed CRC value in decision block 278. If the CRC does not match, the received data block is rejected (declared as erroneous, processing block 276). If the CRC does match, the received data block is accepted (declared as a good data block, processing block 279). The calculation of this normalized correlation metric is described in more detail below.

Referring to FIGS. 3a and 3b, the correlation metric formulation of an example embodiment will be described. As shown at processing block 310 in FIG. 3a, each received soft bit (see also FIG. 2a) may be normalized according to the signal to noise level of the frame to which it belongs (except when the signal to noise level is below SINR threshold (e.g. 0 dB); in this case, no normalization is performed. This SINR threshold could also be ‘infinity’ (or practically speaking >20 db) which means no normalization is performed).This normalization is performed to prevent strong soft bits from having a dominant effect on the correlation value. For example, suppose that each block is interleaved on FramesPerBlock frames (e.g., 8). SlotsCirLin[0] reflects the signal to noise level of frame (n-7) and SlotsCirLin (7) reflects the signal to noise level of frame (n). Thus, for the each frame (k frame) as shown in processing block 310, a normalized metric, NormMetric[k], is generated as follows:

$$NormMetric [ k ] = \frac{1}{SlotsCirLin [ k ]} ,$$

where SlotsCirLin[k] is the linear estimated signal to noise level for each frame (where the frame number k is ranging from 0 to FramesPerBlock-1). Then, an absolute value summation, SumAbsVal, is generated in processing block 312 to bring the correlation metric into the range [0,1] as follows:

$$SumAbsVal = {\sum }_{k = 0}^{NumOfConvOutBits} \vert InpCodeWord [ k ] * NormMetric [ k \% FramesPerBlock ] \vert ,$$

where NumOfConvOutBits is the number of coded bits (e.g. 378) and InpCodeWord[k] is the input block's soft symbols after equalization. Then, in processing block 314, the correlation metric is generated as follows:

$$CorrelationMetric = \frac{1}{SumAbsVal} {\sum }_{k = 0}^{NumOfConvOutBits} InpCodeWord [ k ] * NormMetric [ k \% FramesPerB \text{?} * ( 2 CodeWord [ k ] - 1 ) , \\ \text{?} \text{indicates text missing or illegible when filed}$$

where CodeWord[k] is the bit-stream after re-encoding. The operation % is modulo. This operation is done because subsequent bits inside the block are interleaved to subsequent frames inside the interleaving window (FramesPerBlock). The normalization by SumAbsVal is done to bring the correlation metric into the range [0,1]. The metric is generated to be independent of the signal to noise level. Processing then continues at the bubble A illustrated in FIG. 2b, where the generated normalized correlation metric and the CRC value of the input data block is checked.

FIG. 3b depicts a block diagram of the decoding and re-encoding processes in an example GSM modem. In this example, eight input frames are received in a data block in processing block 352. These frames are equalized (each frame separately, as performed inside processing block 352) and interleaved. A de-interleaving operation is performed on the frames in processing block 354. Then, soft symbols are extracted in processing block 356 (done after the de-interleaver to save processing overhead in the re-encoding process). In addition in processing block 357, a de-puncturing operation is performed, as the de-punctured bits should not be included in the correlation metric because they do not add any additional information.

In processing block 359, a Viterbi decoding operation is performed on the frame data bits. After the Viterbi decoder operation, the un-coded bits from the input data block are re-encoded in processing blocks 361, 363, and 365. The first 50 bits out of 182 class 1 bits, in this example, are protected by three parity bits used for error detection. The 182 information and parity bits of class 1 are reordered in processing block 361, defining 189 information plus parity plus tail bits of class 1. These bits are encoded in processing block 363 with the ½ rate convolution code and a puncturing operation is performed on the coded bits in processing block 365 to produce 378 re-coded hard bits. These re-encoded bits can be provided as input to the generation of the normalized correlation metric in processing block 264. Processing then continues at the bubble A illustrated in FIG. 2b, where the generated normalized correlation metric and the CRC value of the input data block is checked.

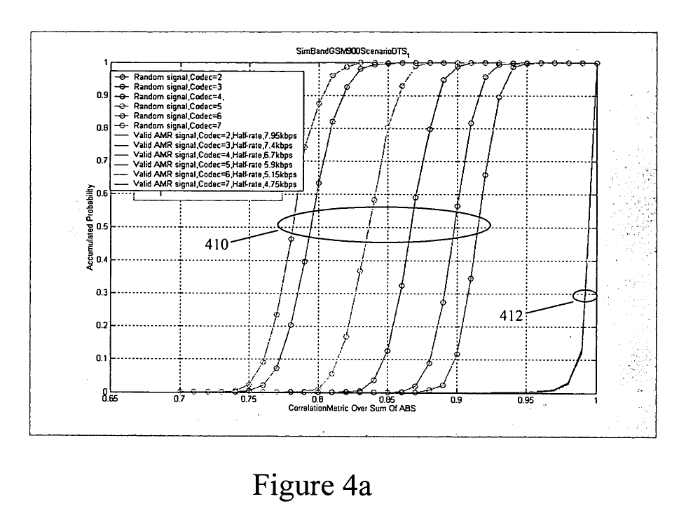

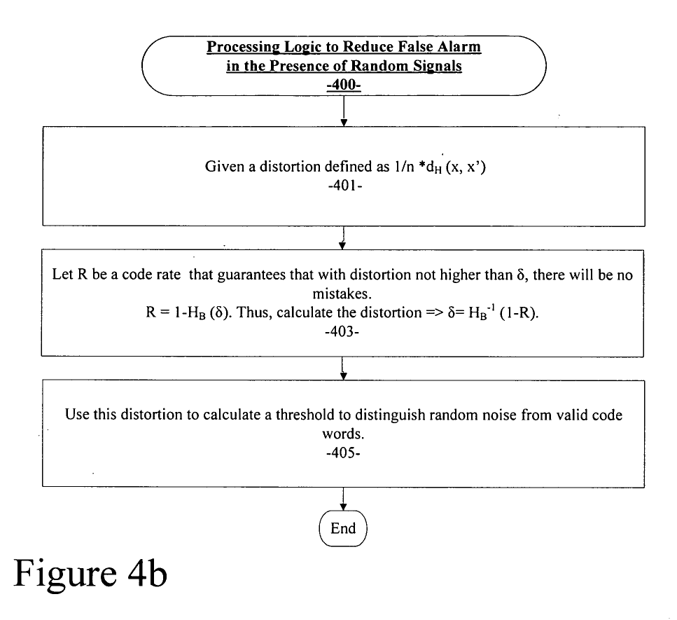

Referring to FIG. 4a, the accumulated probability of the normalized correlation metric is illustrated (correlation between soft symbols {LLR−log likelihood ratio} and hard re-encoded symbols according to formula described above). The left six curves 410 represent the cumulative distribution function (CDF) of the normalized correlation metric under random noise (not a valid code word, e.g. Gmsk (Gaussian minimum shift keying) signal modulated by random bits) for different code rates (e.g. different codec mode in GSM-AMR speech. GSM-AMR is a speech codec standard adapted by 3GPP. The correlation metric was calculated under different code rates in the receiver while the transmitter generated random bits).

The right six curves 412 (appearing one on top of the other) represent the CDF of the normalized correlation metric under valid code words (e.g. valid GSM AMR code words after convolution encoding) for a different code rate (The correlation metric was calculated under different code rates in the receiver while the transmitter generated valid code words). From curves shown in FIG. 4a (and also from rate distortion theory described in more detail below in relation to FIG. 4b), the threshold to distinguish random noise from valid code words can be determined (e.g. it can be seen from the curves shown in the example of FIG. 4a that a threshold of 0.95 is good for GSM AMR\AFS cases to distinguish random noise {curves 410} from valid code words {curves 412}).

The accurate spectrum of the distances between all the random words of length N and the closest code word of convolution code is untraceable. Under the assumption that the convolution code is a good source code, a rate distortion computation is used that will give an upper bound on the minimum expected Hamming distance.

Referring to FIG. 4b, a bound on the distortion can be determined and used to calculate a threshold to distinguish random noise from valid code words. Consider a Bernoulli Source with: Prob (1)=Prob (0)=0.5. Distortion will be defined as 1/n *d_{H}(x, x′), and a code rate is computed that guarantees that with distortion not higher than δ, there will be no mistakes (processing block 401). The computed code rate is: R=1−HB (δ)=>δ=H_{B}⁻¹ (1−R)=>Expected minimum Hamming Distance>=2*n*H_{B}⁻¹ (1−R). (processing block 403). An example of the application of this procedure is given in the table below. This expected minimum Hamming distance, which describes the minimum expected Hamming distance between closest code words, can be used to derive a threshold to distinguish random noise from valid code words (processing block 405). In this example below, the code rate is ½, the code word length is 378, thus to have no mistakes, the minimum expected Hamming distance should be higher than 83. This means that a mistake in more than 42 bits could cause an error and bring us to another code word (e.g. to the closest code word). More than 42 erroneous bits, means that the Expected Correlation ratio should be less than 0.77. Using this number, together with CDF curves from FIG. 4a, a threshold is derived to distinguish random noise from valid code words.

TABLE 1
Minimum Expected Hamming Distance between SPEECH
code words for GSM TCH FS

| | | Minimum | |
|---|---|---|---|
| | | Expected | |
| | | Hamming | Expected |
| | | distance between | Correlation ratio |
| | | closest code | (STATIC channel): |
| | | words | Random/Valid |
| | Code | 2 * d = 2 * n * H_{B}⁻¹ | Sequence |
| Channel | Rate (k/n) | (1 − R) | ((n − d)² − d²)/n² |
| TCH-FS (from | ½ | 2 * 378 * 0.11 = 83 | ((378 − 42)\hat{ }2 − 42\hat{ }2)/ |
| GSM) | | | 378\hat{ }2 = 0.777 |

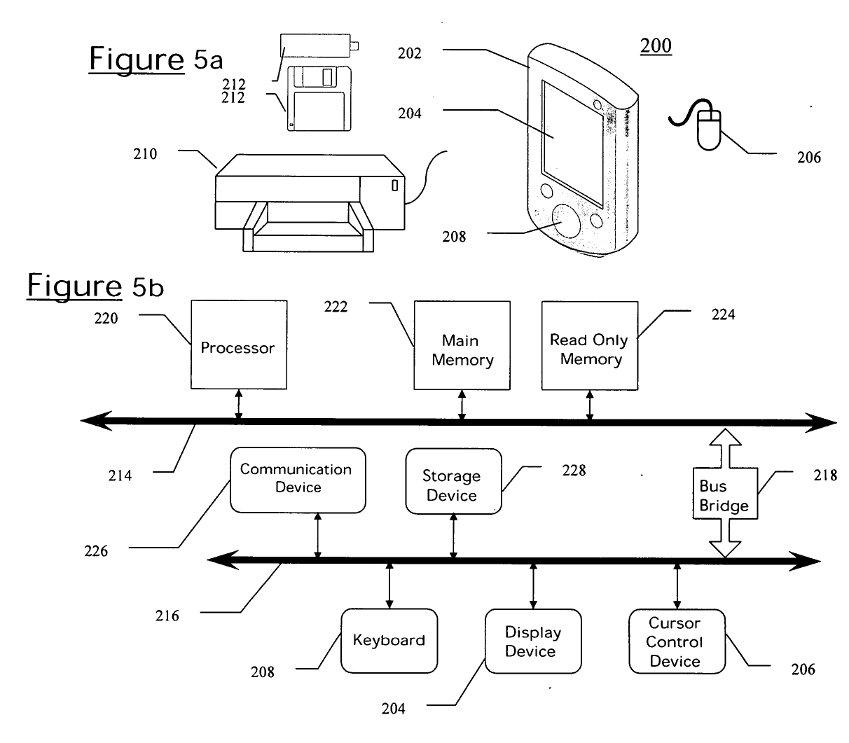

FIGS. 5a and 5b show an example of a computer system 200 illustrating an exemplary client computer system in which the features of an example embodiment may be implemented. A handheld computing device is illustrated by example in FIG. 5a. It will be apparent to those of ordinary skill in the art that the embodiments described and claimed herein can also be implemented in other types of mobile devices, laptop computers, desktop computer systems, servers, and the like. Computer system 200 is comprised of a bus or other communications means 214 and 216 for communicating information, and a processing means such as processor 220 coupled with bus 214 for processing information. Computer system 200 further comprises a random access memory (RAM) or other dynamic storage device 222 (commonly referred to as main memory), coupled to bus 214 for storing information and instructions to be executed by processor 220. Main memory 222 also may be used for storing temporary variables or other intermediate information during execution of instructions by processor 220. Computer system 200 also comprises a read only memory (ROM) and/or other static storage device 224 coupled to bus 214 for storing static information and instructions for processor 220.

An optional data storage device 228 such as a magnetic disk, optical disk, memory stick, flash memory device, and the like and its corresponding drive may also be coupled to computer system 200 for storing information and instructions. Computer system 200 also typically includes a display device 204, such as a plasma display or liquid crystal display (LCD), for displaying information to a computer user. For example, image, textual, video, or graphical depictions of information may be presented to the user on display device 204. Typically, system 200 includes an input device 208, including function keys coupled to bus 216 for communicating information and/or command selections to processor 220. Another type of user input device is cursor control device 206, such as a conventional mouse, trackball, or other type of cursor direction keys for communicating direction information and command selection to processor 220 and for controlling cursor movement on display 204.

A communication device 226 may also be coupled to bus 216 for accessing remote computers or servers, such as a web server, or other servers via the Internet, for example. The communication device 226 may include a wired or wireless modem, a network interface card, or other well-known interface devices, such as those used for interfacing with Ethernet, Token-ring, wireless, or other types of networks. In any event, in this manner, the computer system 200 may be coupled to a number of servers via a conventional network infrastructure.

The system of an example embodiment includes software, information processing hardware, and various processing steps, as described above. The features and process steps of example embodiments may be embodied in machine or computer executable instructions. The instructions can be used to cause a general purpose or special purpose processor, which is programmed with the instructions to perform the steps of an example embodiment. Alternatively, the features or steps may be performed by specific hardware components that contain hard-wired logic for performing the steps, or by any combination of programmed computer components and custom hardware components. While embodiments are described with reference to the Internet, the method and apparatus described herein is equally applicable to other network infrastructures or other data communications systems.

It should be noted that the methods described herein do not have to be executed in the order described, or in any particular order. Moreover, various activities described with respect to the methods identified herein can be executed in repetitive, simultaneous, recursive, serial, or parallel fashion. Information, including parameters, commands, operands, and other data, can be sent and received in the form of one or more carrier waves through communication device 226.

Upon reading and comprehending the content of this disclosure, one of ordinary skill in the art will understand the manner in which a software program can be launched from a computer-readable medium in a computer-based system to execute the functions defined in the software program described above. One of ordinary skill in the art will further understand the various programming languages that may be employed to create one or more software programs designed to implement and perform the methods disclosed herein. The programs may be structured in an object-orientated format using an object-oriented language such as Java, Smalltalk, or C++. Alternatively, the programs can be structured in a procedure-orientated format using a procedural language, such as assembly or C. The software components may communicate using any of a number of mechanisms well known to those of ordinary skill in the art, such as application program interfaces or inter-process communication techniques, including remote procedure calls. The teachings of various embodiments are not limited to any particular programming language or environment, including hypertext markup language (HTML) and extensible markup language (XML).

Thus, other embodiments may be realized. For example, FIGS. 5a and 5b illustrate block diagrams of an article of manufacture according to various embodiments, such as a computer 200, a memory system 222, 224, and 228, a magnetic disk, optical disk, or flash memory device 212, some other storage device 228, and/or any type of electronic device or system. The article 200 may include a computer 202 (having one or more processors) coupled to a computer-readable medium 212, and/or a storage device 228 (e.g., fixed and/or removable storage media, including tangible memory having electrical, optical, or electromagnetic conductors) or a carrier wave through communication device 226, having associated information (e.g., computer program instructions and/or data), which when executed by the computer 202, causes the computer 202 to perform the methods described herein.

Various embodiments are described. In particular, the use of embodiments with various types and formats of user interface presentations may be described. It will be apparent to those of ordinary skill in the art that alternative embodiments of the implementations described herein can be employed and still fall within the scope of the claims set forth below. In the detail herein, various embodiments are described as implemented in computer-implemented processing logic denoted sometimes herein as the “Software”. As described above, however, the claimed invention is not limited to a purely software implementation.

Thus, a system and method for reducing false alarm in the presence of random signals are disclosed. While the present invention has been described in terms of several example embodiments, those of ordinary skill in the art will recognize that the present invention is not limited to the embodiments described, but can be practiced with modification and alteration within the spirit and scope of the appended claims. The description herein is thus to be regarded as illustrative instead of limiting.

We claim:

1. A method comprising:
receiving a data block having at least one frame;
normalizing soft bits of the data block and re-encoding decoder output bits of the data block;
calculating a normalized correlation metric from the normalized soft bits and re-encoded bits of the data block;
comparing the normalized correlation metric to a threshold; and
rejecting the data block when the normalized correlation metric is below the threshold.

2. The method as claimed in claim 1 further including accepting the data block when the normalized correlation metric is at or above the threshold.

3. The method as claimed in claim 1 wherein the threshold is based in part on a minimum expected Hamming distance between closest code words.

4. The method as claimed in claim 1 wherein the normalized correlation metric is based in part on the signal to noise ratio of a related frame.

5. The method as claimed in claim 1 wherein the threshold is based in part on rate distortion computation.

6. The method as claimed in claim 1 wherein the normalized correlation metric is based in part on a convolution encoding.

7. The method as claimed in claim 1 wherein the normalized correlation metric is based in part on the equalizer output log likelihood ratio (LLR).

8. An article of manufacture embodied as a machine-accessible medium including data that, when accessed by a machine, causes the machine to be operable to:
receive via a GSM data interface a data block having at least one frame;
normalize soft bits of the data block and re-encode decoder output bits of the data block;
calculate a normalized correlation metric from the normalized soft bits and re-encoded bits of the data block;
compare the normalized correlation metric to a threshold; and
reject the data block when the normalized correlation metric is below the threshold.

9. The article of manufacture as claimed in claim 8 further operable to accept the data block when the normalized correlation metric is at or above the threshold.

10. The article of manufacture as claimed in claim 8 wherein the threshold is based on a minimum expected Hamming distance between closest code words.

11. The article of manufacture as claimed in claim 8 wherein the normalized correlation metric is based in part on the signal to noise ratio of a related frame.

12. The article of manufacture as claimed in claim 8 wherein the threshold is based in part on rate distortion computation.

13. The article of manufacture as claimed in claim 8 wherein the normalized correlation metric is based in part on a convolution encoding.

14. The article of manufacture as claimed in claim 8 wherein the normalized correlation metric is based in part on the equalizer output log likelihood ratio (LLR).

15. A system comprising:
a processor;
a memory coupled to the processor to store a normalized correlation metric and a threshold;
a GSM data interface; and
an erroneous block detector, operably coupled to the processor, the memory, and the GSM data interface, the erroneous block detector operable to receive via the GSM data interface a data block having at least one frame, normalize soft bits of the data block and re-encode decoder output bits of the data block, calculate a normalized correlation metric from the normalized soft bits and re-encoded bits of the data block, compare the normalized correlation metric to a threshold, and reject the data block when the normalized correlation metric is below the threshold.

16. The system as claimed in claim 15 wherein the erroneous block detector is further operable to accept the data block when the normalized correlation metric is at or above the threshold.

17. The system as claimed in claim 15 wherein the threshold is based on a minimum expected Hamming distance between closest code words.

18. The system as claimed in claim 15 wherein the normalized correlation metric is based in part on the signal to noise ratio of a related frame.

19. The system as claimed in claim 15 wherein the threshold is based in part on rate distortion computation.

20. The system as claimed in claim 15 wherein the normalized correlation metric is based in part on a convolution encoding.

21. The system as claimed in claim 15 wherein the normalized correlation metric is based in part on the equalizer output log likelihood ratio (LLR).

22. An apparatus comprising:
an erroneous block detector to receive via a data interface a data block having at least one frame, normalize soft bits of the data block and re-encode decoder output bits of the data block, calculate a normalized correlation metric from the normalized soft bits and re-encoded bits of the data block, compare the normalized correlation metric to a threshold, and reject the data block when the normalized correlation metric is below the threshold.

23. The apparatus as claimed in claim 22 wherein the erroneous block detector is further operable to accept the data block when the normalized correlation metric is at or above the threshold.

24. The apparatus as claimed in claim 22 wherein the threshold is based on a minimum expected Hamming distance between closest code words.

25. The apparatus as claimed in claim 22 wherein the normalized correlation metric is based in part on the signal to noise ratio of a related frame.

26. The apparatus as claimed in claim 22 wherein the threshold is based in part on rate distortion computation.

27. The apparatus as claimed in claim 22 wherein the normalized correlation metric is based in part on a convolution encoding.

28. The apparatus as claimed in claim 22 wherein the normalized correlation metric is based in part on the equalizer output log likelihood ratio (LLR).
